(19) United States
(12) Patent Application Publication
(10) Pub. No.: US 2026/0348634 A1
(43) Pub. Date: Nov. 5, 2026

(54) COMPRESSOR SURGE PREDICTION AND CONTROL SYSTEM

(71) Applicant: Tyco Fire & Security GmbH, Neuhausen am Rheinfall (CH)

(72) Inventors: Stephen Patrick Arthur, Roanoke, VA (US); Clinton Lee Perdue, Salem, VA (US); David Andrew Bradshaw, Manchester, MD (US); Robert J. Field, Fincastle, VA (US)

(21) Appl. No.: 19/487,418

(22) PCT Filed: May 24, 2024
(86) PCT No.: PCT/US2024/031035

§ 371 Date: Nov. 24, 2025

Related U.S. Application Data
(60) Provisional application No. 63/469,067, filed on May 26, 2023.

(51) Int. Cl. F25B 49/02; F04D 27/00; F04D 27/02; F16C 32/04; F25B 31/00; G01M 13/045; G01R 19/00

(52) U.S. Cl. CPC F25B 49/022; F04D 27/001; F04D 27/02; F16C 32/0451; F16C 32/048; F25B 31/00; G01M 13/045; G01R 19/0092; F16C 2360/44; F16C 2362/52

(57) ABSTRACT

A heating, ventilation, air conditioning, and refrigeration (HVAC&R) system includes a compressor having a shaft and a bearing system configured to support the shaft during rotation, a plurality of sensors configured to detect a plurality of operating parameter values of the compressor, the bearing system, or both, and a control system communicatively coupled to the plurality of sensors. The control system is configured to receive data indicative of the plurality of operating parameter values from the plurality of sensors, determine a rate of change of a steady state force applied to the shaft by the bearing system based on data received from a first sensor of the plurality of sensors, determine a vibration value of the shaft based on data received from a second sensor of the plurality of sensors, and predict an incipient surge condition of the compressor based on the rate of change and the vibration value.

### CROSS-REFERENCE TO RELATED APPLICATIONS

This application claims priority from and the benefit of U.S. Provisional Patent Application No. 63/469,067, entitled “SYSTEM AND METHOD TO PREDICT AND CONTROL COMPRESSOR SURGE,” filed May 26, 2023, which is hereby incorporated by reference in its entirety for all purposes.

### BACKGROUND

This section is intended to introduce the reader to various aspects of art that may be related to various aspects of the present disclosure, which are described below. This discussion is believed to be helpful in providing the reader with background information to facilitate a better understanding of the various aspects of the present disclosure. Accordingly, it should be understood that these statements are to be read in this light, and not as admissions of prior art.

Heating, ventilation, air conditioning, and refrigeration (HVAC&R) systems, such as chiller systems and/or other vapor compression systems, utilize a working fluid (e.g., a refrigerant) that changes phases between vapor, liquid, and combinations thereof in response to exposure to different temperatures and pressures within components of the HVAC&R system. The HVAC&R system may include a working fluid circuit having one or more heat exchangers configured to place the working fluid in a heat exchange relationship with an additional fluid (e.g., cooling fluid, conditioning fluid, water) in order to condition (e.g., heat and/or cool) the additional fluid. The HVAC&R system may deliver the additional fluid to conditioning equipment and/or a conditioned environment serviced by the HVAC&R system. In such applications, the additional fluid may be directed through downstream equipment, such as air handlers, to condition other fluids, such as air in a building. The HVAC&R system may include a compressor configured to pressurize and circulate the working fluid through the working fluid circuit and, thus, enable the transfer of thermal energy between the working fluid and the additional fluid to be conditioned via the heat exchanger.

Compressors (e.g., centrifugal compressors) may be designed for certain operating conditions, which may include one or more characteristics or parameters of the working fluid (e.g., refrigerant). For example, compressors may be designed and/or selected for implementation in the HVAC&R system based on working fluid flow, working fluid temperature and pressure conditions, compressor speed, and so forth. Operation of the compressor may be controlled to operate within various design conditions and/or to avoid undesired operation or operating conditions, such as compressor surge and/or compressor stall. Unfortunately, it may be difficult to avoid undesired compressor operating conditions in some instances. Additionally, operation of the compressor within certain operating conditions that avoid compressor surge and/or stall may result in inefficient operation of the compressor. Accordingly, improved compressor control systems that avoid undesired operating conditions while also enabling more efficient compressor operation are desired.

### SUMMARY

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

In an embodiment of the present disclosure, a heating, ventilation, air conditioning, and refrigeration (HVAC&R) system includes a compressor having a shaft and a bearing system configured to support the shaft during rotation, a plurality of sensors configured to detect a plurality of operating parameter values of the compressor, the bearing system, or both, and a control system communicatively coupled to the plurality of sensors. The control system is configured to receive data indicative of the plurality of operating parameter values from the plurality of sensors, determine a rate of change of a steady state force applied to the shaft by the bearing system based on data received from a first sensor of the plurality of sensors, determine a vibration value of the shaft based on data received from a second sensor of the plurality of sensors, and predict an incipient surge condition of the compressor based on the rate of change and the vibration value.

In another embodiment of the present disclosure, a control system for a heating, ventilation, air conditioning, and refrigeration (HVAC&R) system is configured to receive first data from a first sensor of the control system, where the first data is indicative of a position of a shaft of a centrifugal compressor, receive second data from a second sensor of the control system, where the second data is indicative of an amount of electrical current supplied to a magnetic bearing configured to support the shaft of the centrifugal compressor, determine a vibration parameter of the shaft based on the first data, determine a steady state force applied to the shaft by the magnetic bearing based on the second data, identify an incipient surge condition of the centrifugal compressor based on the vibration parameter and the rate of change of the steady state force, and adjust operation of the centrifugal compressor based on identification of the incipient surge condition.

In a further embodiment of the present disclosure, a chiller of a heating, ventilation, air conditioning, and refrigeration (HVAC&R) system includes a compressor having a motor and a shaft configured to drive rotation of an impeller, a magnetic bearing configured to support the shaft, a current sensor configured to detect a magnitude of an electrical current supplied to the magnetic bearing, and a position sensor coupled to the magnetic bearing and configured to detect a position of the shaft relative to the magnetic bearing. The chiller also includes a magnetic bearing controller configured to supply the electrical current to the magnetic bearing, where the magnetic bearing controller is configured to receive first data indicative of the magnitude of electrical current and receive second data indicative of the position of the shaft relative to the magnetic bearing; and the magnetic bearing controller is configured to generate a signal based on the first data and the second data. The chiller further includes a chiller controller communicatively coupled to the magnetic bearing controller, where the chiller controller is configured to regulate operation of the compressor, receive the signal from the magnetic bearing controller, compare a value of the signal to a threshold value, and identify an incipient surge condition of the compressor based on comparison of the value of the signal to the threshold value.

### BRIEF DESCRIPTION OF THE FIGURES

Various aspects of this disclosure may be better understood upon reading the following detailed description and upon reference to the drawings in which:

FIG. 1 is a perspective view of an embodiment of a building that may utilize a heating, ventilation, air conditioning, and refrigeration (HVAC&R) system in a commercial setting, in accordance with an aspect of the present disclosure;

FIG. 2 is a perspective view of an embodiment of a vapor compression system, in accordance with an aspect of the present disclosure;

FIG. 3 is a schematic of an embodiment of a vapor compression system, in accordance with an aspect of the present disclosure;

FIG. 4 is a schematic of an embodiment of a vapor compression system, in accordance with an aspect of the present disclosure;

FIG. 5 is a cross-sectional side view of an embodiment of a portion of a vapor compression system, illustrating a compressor having magnetic bearings and a control system of the vapor compression system, in accordance with an aspect of the present disclosure;

FIG. 6 is a cross-sectional side view of an embodiment of a portion of a vapor compression system, illustrating a compressor having bearings lubricated via a working fluid of the vapor compression system and a control system of the vapor compression system, in accordance with an aspect of the present disclosure;

FIG. 7 is a schematic of a portion of an embodiment of a vapor compression system, illustrating a compressor and a control system, in accordance with an aspect of the present disclosure; and

FIG. 8 is a schematic of an embodiment of a control system of a vapor compression system, in accordance with an aspect of the present disclosure.

### DETAILED DESCRIPTION

One or more specific embodiments of the present disclosure will be described below. These described embodiments are examples of the presently disclosed techniques. Additionally, in an effort to provide a concise description of these embodiments, all features of an actual implementation may not be described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features.

As used herein, the terms “approximately,” “generally,” and “substantially,” and so forth, are intended to convey that the property value being described may be within a relatively small range of the property value, as those of ordinary skill would understand. For example, when a property value is described as being “approximately” equal to (or, for example, “substantially similar” to) a given value, this is intended to mean that the property value may be within +/−5%, within +/−4%, within +/−3%, within +/−2%, within +/−1%, or even closer, of the given value. Similarly, when a given feature is described as being “substantially parallel” to another feature, “generally perpendicular” to another feature, and so forth, this is intended to mean that the given feature is within +/−5%, within +/−4%, within +/−3%, within +/−2%, within +/−1%, or even closer, to having the described nature, such as being parallel to another feature, being perpendicular to another feature, and so forth. Further, it should be understood that mathematical terms, such as “planar,” “slope,” “perpendicular,” “parallel,” and so forth are intended to encompass features of surfaces or elements as understood to one of ordinary skill in the relevant art, and should not be rigidly interpreted as might be understood in the mathematical arts. For example, a “planar” surface is intended to encompass a surface that is machined, molded, or otherwise formed to be substantially flat or smooth (within related tolerances) using techniques and tools available to one of ordinary skill in the art. Similarly, a surface having a “slope” is intended to encompass a surface that is machined, molded, or otherwise formed to be oriented at an angle (e.g., incline) with respect to a point of reference using techniques and tools available to one of ordinary skill in the art.

As mentioned above, a heating, ventilation, air conditioning, and refrigeration (HVAC&R) system may be used to thermally regulate a space within a building, home, or other suitable structure. For example, the HVAC&R system may include a vapor compression system (e.g., a chiller system, heat pump system) configured to transfer thermal energy between a working fluid (e.g., refrigerant, heat transfer fluid) and a fluid to be conditioned (e.g., air, water, or brine). The vapor compression system may include a working fluid circuit (e.g., vapor compression circuit) that includes one or more heat exchangers (e.g., a condenser and an evaporator) that are fluidly coupled to one another via one or more conduits. Further, the working fluid circuit may include a compressor configured to pressurize and circulate the working fluid through the working fluid circuit and thereby enable the transfer of thermal energy between the working fluid and the fluid to be conditioned via the one or more heat exchangers.

Compressors (e.g., centrifugal compressors) may be designed for certain operating conditions, which may include one or more characteristics or parameters of the working fluid (e.g., refrigerant). For example, compressors may be designed and/or selected for implementation in the HVAC&R system based on working fluid flow (e.g., flow rate), working fluid temperature and pressure conditions at a suction inlet of the compressor, and/or working fluid temperature and pressure conditions at a discharge outlet of the compressor. In some applications, the compressor may be configured to achieve a desired lift (e.g., pressure differential) of the working fluid directed through the working fluid circuit. The lift or “head” of the compressor may be defined as the work or productivity of the compressor and may be expressed as a difference in compressor discharge pressure and compressor suction pressure (e.g., pressure differential). Operation of the compressor may be controlled to enable operation within various design conditions (e.g., parameters) and/or to avoid undesired operation or operating conditions, such as compressor surge and/or compressor stall. As will be appreciated, compressor surge may be described as an unstable operating condition in which an excessive pressure differential across the compressor and/or an insufficient flow of working fluid through the compressor causes an interruption in steady flow of the working fluid through the compressor and, in some instances, causes a reversal of working fluid flow through the compressor.

To characterize compressor operating conditions pertaining to surge, a compressor performance map correlating pressure ratios and mass flow rates of the compressor may be defined may include a surge line across which the compressor will experience surge conditions. In traditional systems, compressors are operated at corresponding pressure ratios and mass flow rates (e.g., operating points) that are sufficiently distant from the surge line on the compressor performance map to reliably avoid surge conditions. Unfortunately, operation of the compressor at operating points (e.g., corresponding pressure ratios and mass flow rates) farther from the surge line generally results in less efficient operation of the compressor, such as operation at greater operating speeds, and therefore greater energy consumption, than demanded to satisfy a load on the HVAC&R system.

Accordingly, present embodiments are directed to systems and methods for predicting and avoiding compressor surge conditions in a more reliable manner. In this way, HVAC&R systems incorporating the present techniques may operate compressors at operating points on a performance map of the compressor that are closer to the surge line while also avoiding onset of surge conditions. As described in further detail below, present embodiments include the utilization of sensor data and/or feedback associated with one or more bearings of the compressor to evaluate compressor operation, predict incipient surge conditions, and implement requisite remedial actions to avoid the onset of surge conditions (e.g., actual surge conditions). For example, the sensor data and/or feedback may be indicative of a position (e.g., radial position, axial position) of a shaft of the compressor, a force (e.g., radial force, axial force) exerted on the shaft of the compressor, or both. The sensor data and/or feedback may be evaluated, processed, and/or compared to one or more threshold values (e.g., threshold values) to predict whether a surge condition is approaching and/or expected. Additionally, the present systems and methods may incorporate machine learning techniques to enable iterative adjustment of the one or more threshold values based on collected and recorded operating data of the HVAC&R system. In this way, prediction and avoidance of surge conditions may be continually improved with subsequent operation of the HVAC&R system, which may enable more efficient operation of the HVAC&R system over time.

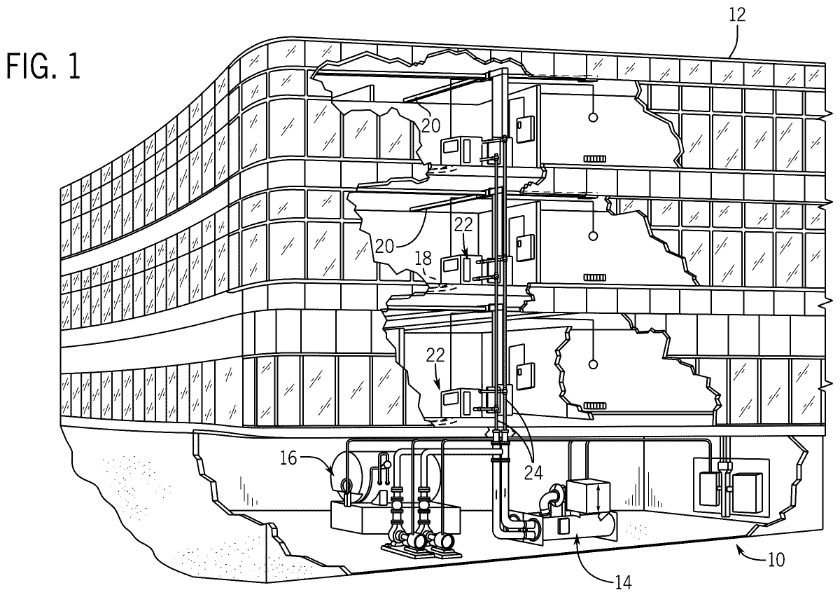

Turning now to the drawings, FIG. 1 is a perspective view of an embodiment of a heating, ventilating, air conditioning, and/or refrigeration (HVAC&R) system 10 in a building 12 for a typical commercial setting. The HVAC&R system 10 may include a vapor compression system 14 (e.g., a chiller) configured to supply a chilled liquid (e.g., a conditioning fluid), which may be used to cool the building 12. The HVAC&R system 10 may also include a boiler 16 configured to supply a warm liquid to heat the building 12. The vapor compression system 14, also referred to herein as a chiller, may circulate a working fluid (e.g., refrigerant) that is cooled by a cooling fluid (e.g., a liquid, such as water) in a condenser of the vapor compression system 14, and that is heated by a conditioning fluid (e.g., a liquid, such as water) in an evaporator of the vapor compression system 14. In some embodiments, the cooling fluid may be provided by a cooling tower which cools the cooling fluid via, for example, heat transfer with ambient air. The conditioning fluid, cooled by the working fluid as noted above, may be utilized to cool an air flow provided to conditioned spaces of the building 12.

The HVAC&R system 10 may also include an air distribution system which circulates air through the building 12. The air distribution system may include an air return duct 18, an air supply duct 20, and/or an air handler 22. In some embodiments, the air handler 22 may include a heat exchanger that is connected to the boiler 16 and the vapor compression system 14 by conduits 24. The heat exchanger in the air handler 22 may receive either heated liquid from the boiler 16 or the conditioning fluid (e.g., chilled liquid, such as water) from the vapor compression system 14, depending on the mode of operation of the HVAC&R system 10. The HVAC&R system 10 is shown with a separate air handler on each floor of the building 12, but in other embodiments, the HVAC&R system 10 may include air handlers 22 and/or other components that may be shared between or among floors.

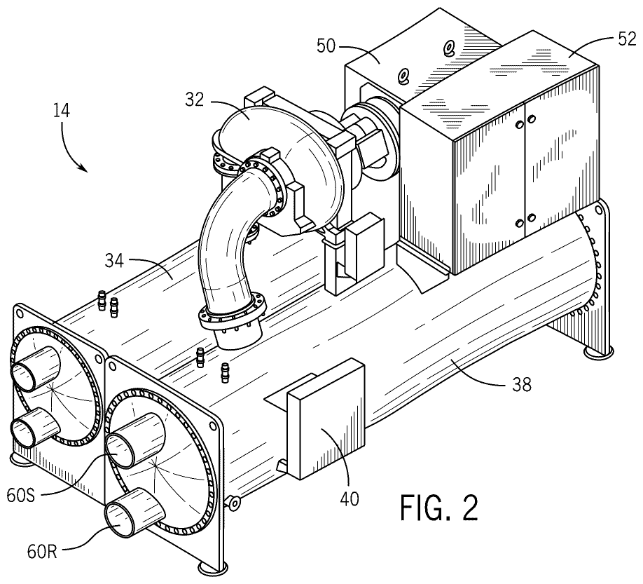

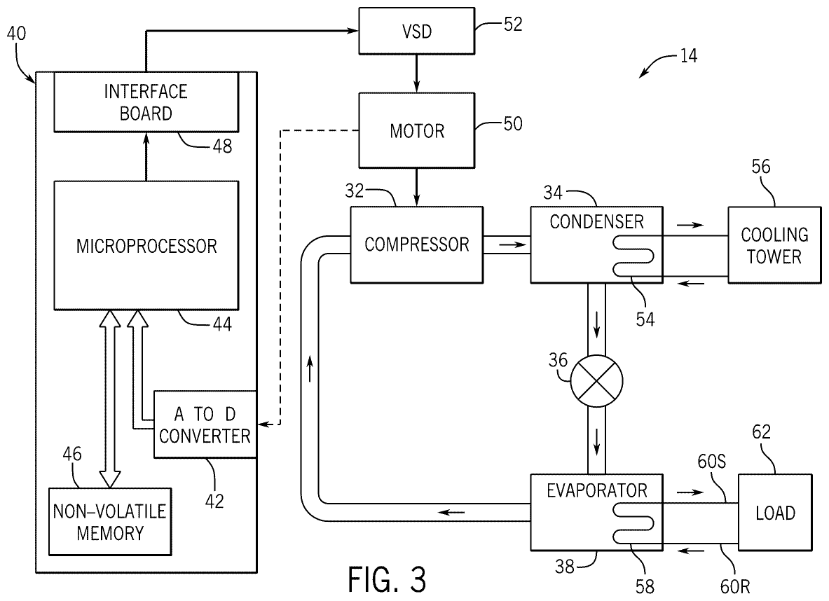

FIGS. 2 and 3 are schematics of embodiments of the vapor compression system 14 (e.g., chiller, chiller system) that may be used in the HVAC&R system 10. The vapor compression system 14 may circulate a working fluid (e.g., a refrigerant) through a circuit (e.g., working fluid circuit, refrigerant circuit) starting with a compressor 32, such as a centrifugal compressor. The circuit may also include a condenser 34, an expansion valve(s) or device(s) 36, and an evaporator 38 (e.g., a liquid chiller). The vapor compression system 14 may further include a control panel 40 that has an analog to digital (A/D) converter 42, a microprocessor 44, a non-volatile memory 46, and/or an interface board 48.

Some examples of fluids that may be used as working fluids (e.g., refrigerants) in the vapor compression system 14 are hydrofluorocarbon (HFC) based working fluids, for example, R-410A, R-407, R-134a, hydrofluoro olefin (HFO), “natural” working fluids like ammonia (NH3), R-717, carbon dioxide (CO2), R-744, or hydrocarbon-based working fluids, water vapor, or any other suitable working fluid. Other possible working fluids that may be circulated through the vapor compression system 14 include R-123, R-514A, R-1224yd, R-1233zd, R-134a, R-1234ze, R-1234yf, R-1311, and R-32. In some embodiments, the vapor compression system 14 may be configured to efficiently utilize working fluids having a normal boiling point of about 19 degrees Celsius (66 degrees Fahrenheit) at one atmosphere of pressure, also referred to as low pressure working fluids, versus a medium pressure working fluid, such as R-134a. As used herein, “normal boiling point” may refer to a boiling point temperature measured at one atmosphere of pressure.

In some embodiments, the vapor compression system 14 may use one or more of a variable speed drive (VSDs) 52, a motor 50, the compressor 32, the condenser 34, the expansion valve or device 36, and/or the evaporator 38. The motor 50 may drive the compressor 32 and may be powered by the VSD 52. The VSD 52 receives alternating current (AC) power having a particular fixed line voltage and fixed line frequency from an AC power source, and provides power having a variable voltage and frequency to the motor 50. In other embodiments, the motor 50 may be powered directly from an AC or direct current (DC) power source. The motor 50 may include any type of motor (e.g., electric motor) that can be powered by a VSD or directly from an AC or DC power source, such as a switched reluctance motor, an induction motor, an electronically commutated permanent magnet motor, or another suitable motor.

The compressor 32 compresses a working fluid vapor and delivers the vapor to the condenser 34 through a discharge passage. In some embodiments, the compressor 32 may be a centrifugal compressor. The working fluid vapor delivered by the compressor 32 to the condenser 34 may transfer heat to a cooling fluid (e.g., water or air) in the condenser 34. The working fluid vapor may condense to a working fluid liquid in the condenser 34 due to thermal heat transfer with the cooling fluid. The liquid working fluid from the condenser 34 may flow through the expansion device 36 and to the evaporator 38. In the illustrated embodiment of FIG. 3, the condenser 34 is water cooled and includes a tube bundle 54 connected to a cooling tower 56, which supplies the cooling fluid to the condenser 34.

The liquid working fluid delivered to the evaporator 38 may absorb heat from a conditioning fluid, which may or may not be the same cooling fluid used in the condenser 34. For example, the conditioning fluid may be cooled by the working fluid in the evaporator 38, and then the conditioning fluid may be utilized in the building 12 to condition (e.g., cool) an air flow provided to condition a space in the building 12. The liquid working fluid in the evaporator 38 may undergo a phase change from the liquid working fluid to a working fluid vapor. As shown in the illustrated embodiment of FIG. 3, the evaporator 38 may include a tube bundle 58 having a supply line 60S and a return line 60R connected to a load 62 (e.g., a cooling load). The conditioning fluid of the evaporator 38 (e.g., water, ethylene glycol, calcium chloride brine, sodium chloride brine, or any other suitable fluid) enters the evaporator 38 via the return line 60R and exits the evaporator 38 via the supply line 60S. The evaporator 38 may reduce the temperature of the conditioning fluid in the tube bundle 58 via thermal heat transfer with the working fluid. The tube bundle 58 in the evaporator 38 may include a plurality of tubes and/or a plurality of tube bundles. In any case, the vapor working fluid exits the evaporator 38 and returns to the compressor 32 by a suction line to complete the cycle.

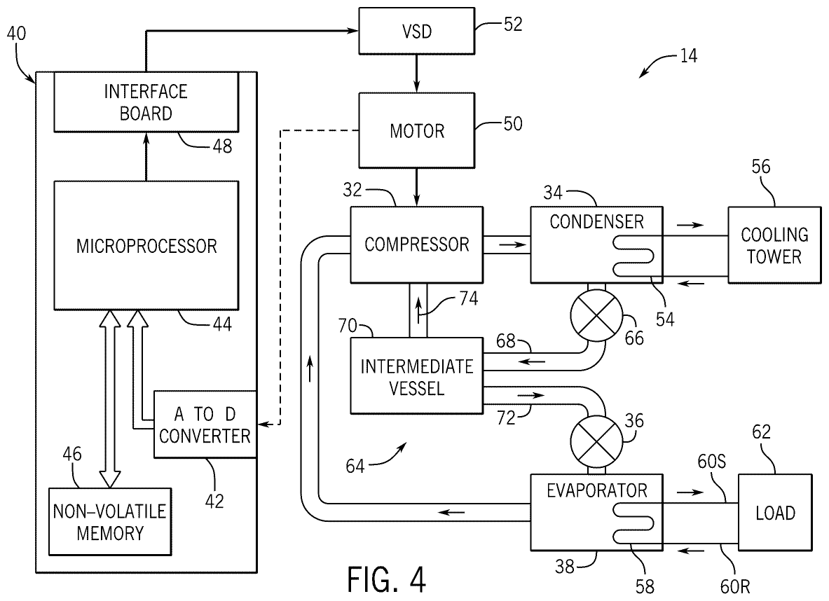

FIG. 4 is a schematic of an embodiment of the vapor compression system 14 with an intermediate circuit 64 incorporated between the condenser 34 and the expansion device 36. The intermediate circuit 64 may have an inlet line 68 that is directly fluidly connected to the condenser 34. In other embodiments, the inlet line 68 may be indirectly fluidly coupled to the condenser 34. As shown in the illustrated embodiment of FIG. 4, the inlet line 68 includes a first expansion device 66 positioned upstream of an intermediate vessel 70. In some embodiments, the intermediate vessel 70 may be a flash tank (e.g., a flash intercooler, an economizer, etc.). In other embodiments, the intermediate vessel 70 may be configured as a heat exchanger or a “surface economizer.” In the illustrated embodiment of FIG. 4, the intermediate vessel 70 is used as a flash tank, and the first expansion device 66 is configured to lower the pressure of (e.g., expand) the liquid working fluid received from the condenser 34. During the expansion process, a portion of the liquid working fluid may vaporize, and thus, the intermediate vessel 70 may be used to separate the vapor working fluid from the liquid working fluid received from the first expansion device 66.

Additionally, the intermediate vessel 70 may provide for further expansion of the liquid working fluid due to a pressure drop experienced by the liquid working fluid when entering the intermediate vessel 70 (e.g., due to a rapid increase in volume experienced when entering the intermediate vessel 70). The vapor working fluid in the intermediate vessel 70 may be drawn by the compressor 32 through a suction line 74 of the compressor 32. In other embodiments, the vapor working fluid in the intermediate vessel 70 may be drawn to an intermediate stage of the compressor 32 (e.g., not the suction stage). The liquid working fluid that collects in the intermediate vessel 70 may be at a lower enthalpy than the liquid working fluid exiting the condenser 34 due to expansion of the working fluid at the expansion device 66 and/or in the intermediate vessel 70. The liquid working fluid from intermediate vessel 70 may then flow through line 72 and through a second expansion device 36 to the evaporator 38.

It should be appreciated that any of the features described herein may be incorporated with the vapor compression system 14 or any other suitable HVAC&R systems. For example, the present techniques may be incorporated with any suitable HVAC&R system having a compressor (e.g., a centrifugal compressor, an axial compressor), such as the compressor 32, with one or more bearings configured to support (e.g., axially support, radially support) and enable rotation of the compressor. The discussion below describes the present techniques incorporated with embodiments of a compressor (e.g., a centrifugal compressor) utilized with a vapor compression system (e.g., vapor compression system 14), such as a chiller system. However, it should be noted that the systems and methods described herein may be incorporated with other embodiments of compressors utilized in other types of systems, as well as other embodiments of the HVAC&R system 10 (e.g., a heat pump system, a refrigeration system, etc.). For example, the present techniques may be incorporated with any suitable compressor that utilizes bearings and that may be susceptible to surge conditions.

As discussed above, present embodiments are directed to systems and methods for predicting and avoiding compressor surge conditions in a more reliable manner that also enables more efficient operation of the compressor and a system (e.g., HVAC&R system 10) in which the compressor is utilized. In particular, the present disclosure is directed to various techniques that utilize sensor data associated with and/or collected by one or more bearing systems of the compressor. As should be appreciated, the bearing systems may be configured to enable rotation of a shaft of the compressor, and the bearing systems may include radial bearings, axial bearings, or both. In some embodiments, the bearing systems include magnetic bearings (e.g., active magnetic bearings). In other embodiments, the bearing systems may include lubricant bearings that utilize a working fluid (e.g., refrigerant, vapor working fluid) circulated through a working fluid circuit by the compressor as a lubricant. Alternatively, the bearing systems may utilize oil as a lubricant to enable desired rotation and positioning of the shaft during operation of the compressor. In any case, sensors of the bearing systems may collect data indicative of various operating parameters (e.g., shaft position, shaft vibration, force applied to the shaft via the bearing, etc.), and the systems described herein may analyze the data to predict a surge condition and/or identify an incipient surge condition. In response, operation of the compressor and/or the HVAC&R system having the compressor may be modified to avoid onset of the surge condition. Indeed, as described further below, the present techniques may enable rapid prediction and/or detection of incipient surge, as well as rapid implementation of remedial measures, which may enable operation of the compressor at operating points closer to a surge line and thereby enable more efficient operation of the compressor. In this way, the compressor may be operated with reduced energy consumption, reduce operational interruption, reduced noise generation, and improved reliability.

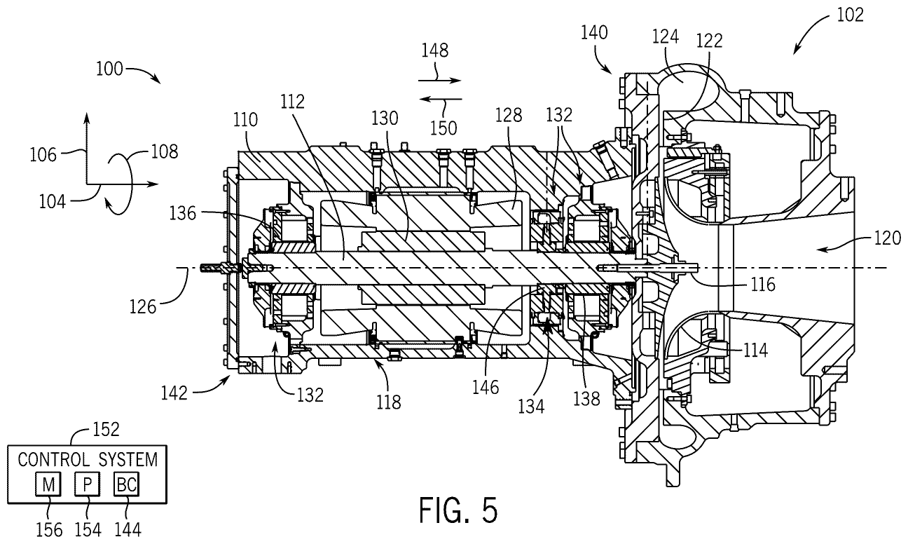

With the foregoing in mind, FIG. 5 is a cross-sectional side view schematic of an embodiment of a vapor compression system 100 (e.g., chiller system, water-cooled chiller, vapor compression system 14, HVAC&R system) including a compressor 102 (e.g., centrifugal compressor, compressor 32). To facilitate the following discussion, the compressor 102 and components thereof may be described with reference to a longitudinal axis or direction 104, a radial axis or direction 106 (e.g., lateral axis or direction, cross-wise to the longitudinal axis or direction 104), and a circumferential direction 108. It should be appreciated that the radial axis or direction 106 may extend radially outward, relative to the longitudinal axis 104, in any suitable direction.

The compressor 102 includes a housing 110 and a shaft 112 extending through the housing 110. The compressor 102 also includes an impeller 114 coupled to the shaft 112, such as via a fastener 116. During operation of the compressor 102, the shaft 112 may rotate, via operation of a motor 118 (e.g., motor 50) and cause rotation of the impeller 114 within the housing 110. Rotation of the impeller 114 may drive a working fluid (e.g., refrigerant) to flow along a working fluid flow path (e.g., working fluid circuit, from the evaporator 38, from the intermediate vessel 70) and to draw the working fluid into the housing 110 via a suction inlet 120 and toward the impeller 114. It should be noted that, in accordance with the present techniques, the compressor 102 does not include inlet guide vanes (e.g., pre-rotation vanes) disposed at or in the suction inlet 120. The impeller 114 may impart mechanical energy to the working fluid and discharge the working fluid toward a diffuser passage 122 of the compressor 102 via an impeller exit or outlet of the impeller 114. The working fluid may be directed from the diffuser passage 122 to a volute 124 of the compressor 102 and from the volute 124 to another component of the HVAC&R system 10 (e.g., the condenser 34) for heat exchange with a fluid, such as a cooling fluid.

As mentioned above, the motor 118 is coupled to the shaft 112 and is configured to drive rotation of the shaft 112 about a rotational axis 126 of the shaft 112 during operation of the compressor 102 to enable rotation of the impeller 114. To this end, the motor 118 includes a stator 128 and a rotor 130. As will be appreciated, the rotor 130 may be securely fastened or attached to the shaft 112, and the stator 128 may be a stationary component that extends circumferentially (e.g., in the circumferential direction 108) about the rotor 130. The stator 128 may impart radial and axial magnetic forces onto the rotor 130 to drive rotation of the rotor 130 and thereby drive rotation of the shaft 112 and the impeller 114.

To enable desired rotation of the shaft 112 within the motor 118 (e.g., within the housing 110), the compressor 102 (e.g., the motor 118) includes a plurality of bearings 132 (e.g., a bearing system, bearing assemblies) disposed circumferentially (e.g., in the circumferential direction 108) about the shaft 112. In the illustrated embodiment, the bearings 132 are magnetic bearings configured to impart magnetic forces onto the shaft 112 and/or components of the shaft 112 to enable desired positioning and/or support of the shaft 112 during operation of the compressor 102. In some embodiments, the bearings 132 may be active magnetic bearings having actuators and/or other features configured to continuously and/or continually receive and/or adjust a current supplied to the bearings 132 to adjust and/or maintain a position of the shaft 112 during rotation. As shown, the bearings 132 include a first bearing 134 (e.g., thrust bearing, axial bearing, magnetic thrust bearing) configured to control and/or adjust a position (e.g., axial position) of the shaft 112 along the rotational axis 126 (e.g., in the longitudinal direction 104) of the shaft 112. For example, the first bearing 134 may be configured to block or limit movement (e.g., translation, axial movement) of the shaft 112 along the rotational axis 126 and/or relative to the longitudinal axis 104. The compressor 102 may also include a second bearing 136 (e.g., first radial bearing, first magnetic radial bearing) and a third bearing 138 (e.g., second radial bearing, second magnetic radial bearing). The second bearing 136 and the third bearing 138 may block movement (e.g., bending, radial movement, eccentric rotation) of the shaft 112 in a direction crosswise to the rotational axis 126, such as in the radial direction 106.

In the illustrated embodiment, the third bearing 138 and the impeller 114 is positioned at or coupled to a first end 140 (e.g., a first axial end, a first longitudinal end) of the shaft 112, and the second bearing 136 is positioned at or coupled to a second end 142 (e.g., a second axial end, a second longitudinal end), opposite the first end 140, of the shaft 112. Additionally, the first bearing 134 is disposed at the first end 140 of the shaft 112, and the third bearing 138 is disposed between the impeller 114 and the first bearing 134 relative to the rotational axis 126 (e.g., the longitudinal axis 104). Thus, the first bearing 134 and the third bearing 138 are disposed opposite the second bearing 136 relative to the motor 118 (e.g., the rotor 130, the stator 128). However, it should be appreciated that the bearings 132 may be arranged along the shaft 112 in other configurations in some embodiments. For example, the first bearing 134 (e.g., thrust bearing) may be disposed at the second end 142 of the shaft 112 adjacent the second bearing 136.

In any case, the bearings 132 are configured to enable desired positioning and rotation of the shaft 112 and the impeller 114 during operation of the compressor 102. Specifically, the bearings 132 are configured to support a load (e.g., axial load, radial load) on the shaft 112 via impart magnetic forces onto the shaft 112 to cause the shaft 112 to levitate within (e.g., radially within, axially within) the bearings 132. To this end, the vapor compression system 100 (e.g., the compressor 102) may include a bearing controller 144 (e.g., magnetic bearing controller) communicatively coupled to the bearings 132 and configured to regulate operation of the bearings 132. The bearing controller 144 may, for example, be configured to regulate a respective flow of current supplied to each bearing 132 to maintain levitation and/or a position of the shaft 112 (e.g., relative to the longitudinal axis 104 and/or the radial axis 106). Similarly, the bearing controller 144 may adjust or alter the respective flow of current supplied to one or more of the bearings 132 to adjust levitation and/or a position (e.g., axial position, radial position) of the shaft 112. For example, the bearing controller 144 may adjust an electrical current provided to the second bearing 136 and/or the third bearing 138 to adjust a magnetic force (e.g., electromagnetic force, magnetic field, radial magnetic force) imparted radially (e.g., radially inward, toward the rotational axis 126) onto the shaft 112.

The bearing controller 144 may also adjust an electrical current provided to the first bearing 134 to adjust a magnetic force (e.g., electromagnetic force, magnetic field, axial magnetic force) imparted onto a collar 146 (e.g., thrust collar, thrust disk) fixedly attached to the shaft 112. For example, the first bearing 134 may include multiple magnetic bearing components (e.g., windings, electromagnets) that are each configured to receive a respective flow of electrical current from the bearing controller 144 and to generate a force along the longitudinal axis 104. Specifically, the collar 146 may extend radially outward from the shaft 112 and may be disposed between the multiple magnetic bearing components (e.g., relative to the longitudinal axis 104) of the first bearing 134. In this way, a first magnetic bearing component of the first bearing 134 may apply a first magnetic force to the collar 146, and therefore the shaft 112, in a first direction 148, and a second magnetic bearing component of the first bearing 134 may apply a second magnetic force to the collar 146 and the shaft 112 in a second direction 150, opposite the first direction 148.

As will be appreciated, operation of the bearings 132 may be controlled by the bearing controller 144 based on data and/or feedback from one or more sensors (e.g., position sensors, current sensors, bearing sensors). In accordance with present techniques, the data and/or feedback from the one or more sensors may also be utilized to predict, control, and/or avoid surge conditions of the compressor 102. Indeed, the one or more sensors associated with the bearings 132 may be configured to collect and provide substantial amounts data and/or feedback (e.g., via high bandwidth communications, via high sampling rates, such as 20,000 times per second) that enable continual (e.g., continuous), rapid, and/or more accurate prediction and/or detection of incipient surge conditions and thereby enable rapid and reliable operational adjustments of the compressor 102 and/or the vapor compression system 100 to avoid onset of surge conditions. Operation and utilization of sensors with the bearings 132 and to enable the disclosed techniques related to prediction and avoidance of compressor surge are described in further detail below.

The bearing controller 144 (e.g., automation controller, electronic controller) may be a component of a control system 152 (e.g., controller, main controller, automation controller, electronic controller, chiller controller) of the vapor compression system 100. The control system 152 may, for example, include the control panel 40 (e.g., chiller controller, main controller) described above. In general, the control system 152 is configured to control and/or regulate operation of the vapor compression system 100 and components thereof, such as the compressor 102 (e.g., the motor 118), one or more fans, one or more valves, a variable speed drive (e.g., VSD 52) associated with the motor 118, and so forth. In some embodiments, the bearing controller 144 may be a separate controller (e.g., separate from the control panel 40 and/or chiller controller) configured to regulate operation of the bearings 132 and may be configured to communicate with other control components (e.g., a main controller) of the control system 152. In other embodiments, the bearing controller 144 may be integrated with the control panel 40, a main chiller controller, or another controller of the vapor compression system 100.

In any case, the control system 152 (e.g., main controller, chiller controller, control panel 40) includes processing circuitry 154, such as one or more microprocessors, which may execute software for controlling the components of the vapor compression system 100 and/or components thereof. The processing circuitry 154 may include multiple microprocessors, one or more “general-purpose” microprocessors, one or more special-purpose microprocessors, and/or one or more application specific integrated circuits (ASICS), or some combination thereof. For example, the processing circuitry 154 may include one or more reduced instruction set (RISC) processors, one or more complex instruction set computer (CISC) processors, one or more field programmable gate arrays (FPGA), one or more integrated circuits, one or more digital signal processors, and so forth.

The control system 152 may also include a memory 156 (e.g., a memory device) that may store information such as instructions (e.g., executable instructions, code, software logic), control software, look up tables, configuration data, etc. The memory 156 may include a volatile memory, such as random access memory (RAM), and/or a nonvolatile memory, such as read-only memory (ROM). The memory 156 may store a variety of information and may be used for various purposes. For example, the memory 156 may store processor-executable instructions including firmware or software for the processing circuitry 154 to execute, such as instructions for controlling components of the vapor compression system 100, the compressor 102, the bearing controller 144, and/or the bearings 132. In some embodiments, the memory 156 is a tangible, non-transitory, machine-readable-medium that may store machine-readable instructions for the processing circuitry 154 to execute. The memory 156 may include ROM, flash memory, a hard drive, or any other suitable optical, magnetic, or solid-state storage medium, or a combination thereof. The memory 156 may store data, instructions, and any other suitable data. It should be appreciated that the memory 156 may store processor-executable instructions (e.g., for execution via the processing circuitry 154) to enable operation of any of the components described herein and to enable any of the functionalities and/or operations described herein. As described in further detail below, the bearing controller 144 or other dedicated controller of the bearings 132 may similarly include processing circuitry and a memory.

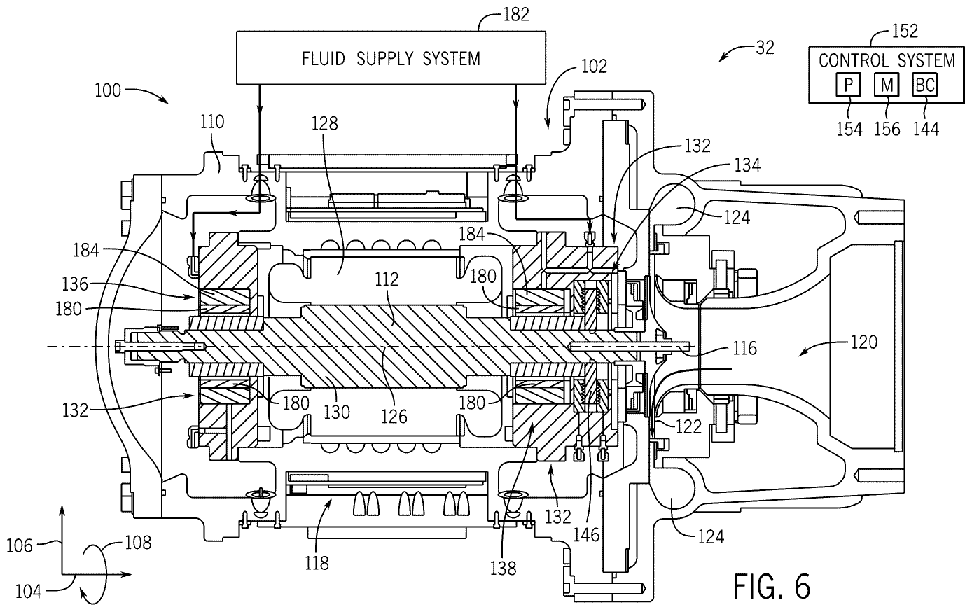

The present techniques may also be incorporated with embodiments of the compressor 102 having other types of bearings 132. For example, FIG. 6 is a cross-sectional side view schematic of an embodiment of the vapor compression system 100 (e.g., chiller system, water-cooled chiller, vapor compression system 14, HVAC&R system) including the compressor 102 (e.g., centrifugal compressor, compressor 32) and the bearings 132. The bearings 132 are configured to receive a pressurized fluid, such as a working fluid (e.g., refrigerant) circulated by the vapor compression system 100, and discharge the pressurized fluid toward the shaft 112 to enable levitation and positional adjustment of the shaft 112 within the compressor 102. The illustrated embodiment includes certain elements and element numbers similar to those discussed above with reference to FIG. 5. For example, the illustrated embodiment of the compressor 102 includes the shaft 112, the impeller 114, the bearings 132 (e.g., first bearing 134, second bearing 136, third bearing 138), the bearing controller 144, the control system 152, and so forth.

As similarly discussed above, the first bearing 134 (e.g., thrust bearing, bearing assembly, porous bearing) is configured to control and/or adjust a position (e.g., axial position) of the shaft 112 along the rotational axis 126. For example, the first bearing 134 may be configured to block or limit movement (e.g., translation) of the shaft 112 along the rotational axis 126. The second bearing 136 (e.g., radial bearing, bearing assembly, porous bearing) and the third bearing 138 (e.g., radial bearing, bearing assembly, porous bearing) are configured to control and/or adjust a position (e.g., radial position) of the shaft 112 relative to the rotational axis 126 (e.g., central axis) of the shaft 112. For example, the second bearing 136 and the third bearing 138 are configured to support a load (e.g., radial load) of the shaft 112 and enable levitation of the shaft 112 within (e.g., radially within) the second bearing 136 and the third bearing 138 (e.g., within the housing 110). The second bearing 136 and the third bearing 138 may also be configured to block movement (e.g., bending, radial movement, eccentric rotation) of the shaft 112 crosswise to the rotational axis 126.

As mentioned above, the vapor compression system 100 is configured to direct a pressurized fluid to the bearings 132, such as the first bearing 134, the second bearing 136, and/or the third bearing 138. The pressurized fluid may be the same working fluid (e.g., refrigerant) circulated through the vapor compression system 100 having the compressor 102. However, it should be appreciated that the pressurized fluid may be any suitable fluid, such as a refrigerant, a condensable vapor, or other fluid. In some embodiments, the first bearing 134, the second bearing 136, and/or the third bearing 138 each include one or more porous elements 180 configured to direct the pressurized fluid therethrough. For example, the one or more porous elements 180 of the second bearing 136 and the third bearing 138 may be configured to received pressurized fluid and direct the pressurized fluid towards the shaft 112 to establish a high-pressure fluid film (e.g., vapor film) about the shaft 112 between the second bearing 136 and the third bearing 138 and the shaft 112. In this way, the pressurized fluid may cause the shaft 112 to levitate from the second bearing 136 and the third bearing 138, thereby enabling desired rotation of the shaft 112 about the rotational axis 126. The one or more porous elements 180 of first bearing 134 may receive pressurized fluid and direct the pressurized fluid towards the collar 146 (e.g., thrust collar) of the first bearing 134. In this way, the pressurized fluid may apply a force to the collar 146 and enable adjustable positioning of the shaft 112 along the rotational axis 126.

The vapor compression system 100 (e.g., the compressor 102) also includes a fluid supply system 182 configured to supply pressurized fluid to the bearings 132 (e.g., first bearing 134, second bearing 136, and/or third bearing 138) of the compressor 102 (e.g., motor 118). For example, the fluid supply system 182 may direct the pressurized fluid through the housing 110 of the compressor 102 to one or more bearing housings 184 (e.g., casings) of the first bearing 134, the second bearing 136, and the third bearing 138. In the illustrated embodiment, one bearing housing 184 is associated with the second bearing 136, and another bearing housing 184 is associated with the third bearing 138. An additional bearing housing 184 may be utilized with the first bearing 134. In other embodiments, the first bearing 134 and the third bearing 138 may be packaged together in a common bearing housing 184. The pressurized fluid may be directed through the bearing housings 184 to the corresponding porous elements 180 retained within each bearing housing 184.

As similarly described above, the illustrated embodiment of the vapor compression system 100 may also include the control system 152 and/or the bearing controller 144. For example, the bearing controller 144 may be configured to regulate operation of the bearings 132 and/or the fluid supply system 182 to enable desired levitation and/or positional adjustment (e.g., radial adjustment, axial adjustment) of the shaft 112 during operation of the compressor 102. For example, the bearing controller 144 may be configured to regulate a flow (e.g., pressure, flow rate, temperature, etc.) of the pressurized fluid directed to one or more of the bearings 132. Additionally, the bearing controller 144 may be configured to regulate operation of the bearings 132 and/or the fluid supply system 182 based on data and/or feedback from one or more sensors. As described in further detail below, the data and/or feedback from one or more sensors associated with the bearings 132 may also be utilized to predict incipient surge and/or surge conditions of the compressor 102 and also enable remedial actions or controls to avoid onset of a surge condition in the compressor 102.

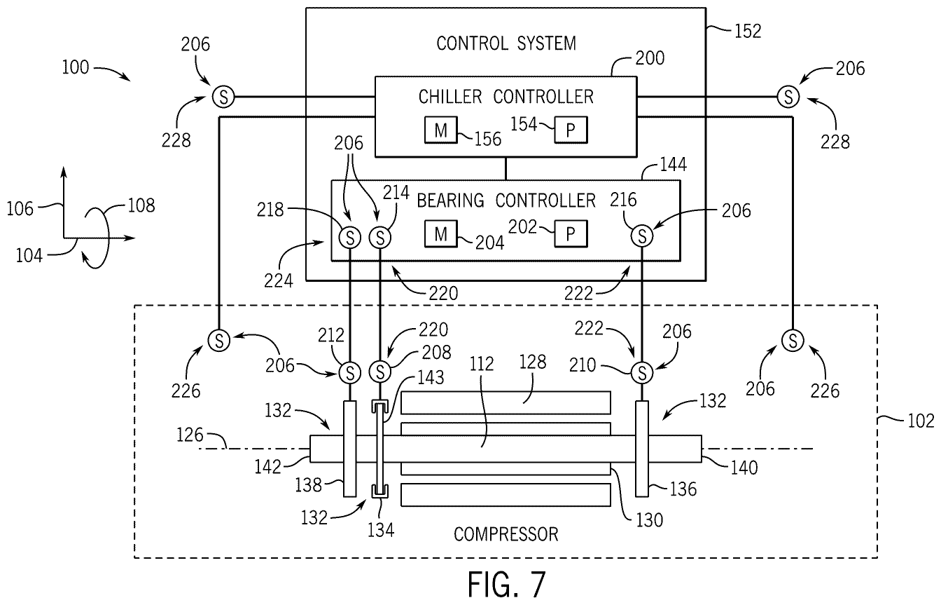

FIG. 7 is a schematic of a portion of an embodiment of the vapor compression system 100, illustrating the compressor 102 having the bearings 132 and the control system 152 configured to predict, control, and/or avoid based on data associated with operation of the bearings 132. The illustrated embodiment includes the first bearing 134 (e.g., thrust bearing) and the collar 146 associated with the first bearing 134, the second bearing 136 (e.g., first radial bearing), and the third bearing 138 (e.g., second radial bearing). The bearings 132 may be magnetic bearings configured to receive electrical current and impart a magnetic force on the shaft 112 and/or collar 146, lubricated bearings, or other suitable type of bearings. Embodiments of the bearings 132 configured as lubricated bearings may be porous bearings configured to receive and discharge a pressurized fluid (e.g., working fluid, refrigerant, refrigerant vapor) toward the shaft 112 and/or the collar 146, as described above with reference to FIG. 6. In other embodiments, the bearings 132 may be lubricated bearings configured to receive a lubricant, such as oil. It should be noted that the compressor 102 is illustrated as a simplified schematic in FIG. 7 to focus on the bearings 132 and features of the control system 152 that enable implementation of the present techniques related to prediction and avoidance of compressor surge. The following discussion describes the present techniques incorporated with the bearings 132 configured as magnetic bearings, but it should be appreciated that the bearings 132 may be any suitable type of bearing for which data and/or feedback associated with operation of the bearings 132 may be collected and utilized to predict, control, and/or avoid surge conditions in the compressor 102.

As discussed above, the control system 152 includes the bearing controller 144 (e.g., magnetic bearing controller) configured to regulate operation of the bearings 132. The control system 152 also includes a chiller controller 200 (e.g., main controller, control panel 40) communicatively coupled to the bearing controller 144. The chiller controller 200 includes the processing circuitry 154 and the memory 156 described above, and the chiller controller 200 is configured to coordinate and regulate operation of the vapor compression system 100 and the components thereof, including the compressor 102. The bearing controller 144 also includes processing circuitry 202 (e.g., one or more digital signal processors) and a memory 204, which may be similar to the processing circuitry 154 and memory 156 discussed above. For example, the memory 156 may store data (e.g., sensor data, reference data, threshold values, etc.), executable instructions (e.g., one or more algorithms) for execution by the processing circuitry 202, and/or other suitable information to enable control of the bearings 132 as well as implementation and execution of the techniques described herein. It should be appreciated that any of the threshold values described herein may be stored on the memory 156.

The control system 152 also includes a plurality of sensors 206 communicatively coupled to the bearing controller 144, the chiller controller 200, or both. The sensors 206 are configured to detect various operating conditions and/or parameters associated with operation of the compressor 102 and/or the bearings 132. For example, one or more of the sensors 206 may be configured to detect a parameter indicative of a speed of the shaft 112, a position of the shaft 112 (e.g., relative to one of the bearings 132), such as a radial position and/or an axial position of the shaft 112 (e.g., relative to one of the bearings 132), a vibration frequency of the shaft 112, a magnitude and/or amplitude of vibration of the shaft 112, a temperature of the shaft 112, a flow rate of working fluid through the compressor 102, a temperature and/or a pressure of the working fluid directed through the compressor 102, a parameter of an electrical current supplied to one or more of the bearings 132 (e.g., magnetic bearings), another operating parameter of one or more of the bearings 132, a temperature, pressure, and/or flow rate of a pressurized fluid supplied to one or more of the bearings 132 (e.g., porous bearings), another suitable operating parameter, or any combination thereof. As will be appreciated, one or more of the sensors 206 may be utilized to detect an operating parameter associated with traditional operation of the bearings 132. However, the present techniques enable utilization, analysis, and/or manipulation of the data detected by one or more of the sensors 206 to further enable prediction, control, and/or avoidance of compressor surge and/or surge conditions. In this way, the present techniques enable improved (e.g., more rapid, more reliable) prediction of compressor surge while also mitigation additional costs (e.g., equipment costs) incurred to implement the present techniques. That is, the present techniques may be implemented by utilizing certain components of the compressor 102 that may be traditionally incorporated with the compressor 102 for other purposes unrelated to prediction, control, and/or avoidance of compressor surge.

In the illustrated embodiment, the sensors 206 include a first position sensor 208 associated with (e.g., integrated with) the first bearing 134, a second position sensor 210 associated with (e.g., integrated with) the second bearing 136, and a third position sensor 212 associated with (e.g., integrated with) the third bearing 138. Each of the first position sensor 208, the second position sensor 210, and the third position sensor 212 may be configured to detect a position of the shaft 112 and/or the collar 146. For example, the first position sensor 208 may be an axial position sensor (e.g., eddy current sensor, proximity sensor) configured to detect an axial position (e.g., along the longitudinal axis 104) of the collar 146 and/or the shaft 112 (e.g., relative to the first bearing 134). The second position sensor 210 and the third position sensor 212 may each be a radial position sensor (e.g., eddy current sensor, proximity sensor) configured to detect a radial position of the shaft 112 relative to the longitudinal axis 104 and/or relative to second bearing 136 and the third bearing 138, respectively.

In some embodiments, one or more of the sensors 206 may be incorporated and/or integrated with the bearing controller 144. For example, in embodiments of the bearing controller 144 configured as a magnetic bearing controller configured to supply electrical current to the bearings 132, the bearing controller 144 may include a first current sensor 214 associated with the first bearing 134 (e.g., magnetic bearing, active magnetic bearing), a second current sensor 216 associated with the second bearing 136 (e.g., magnetic bearing, active magnetic bearing), and a third current sensor 318 associated with the third bearing 138 (e.g., magnetic bearing, active magnetic bearing). Each of the first current sensor 214, the second current sensor 216, and the third current sensor 218 may be configured to detect a value indicative of an amount, magnitude, or other metric associated with the electric current supplied to the corresponding bearing 132 (e.g., to a respective actuator, amplifier, coil, wire of the corresponding bearing 132).

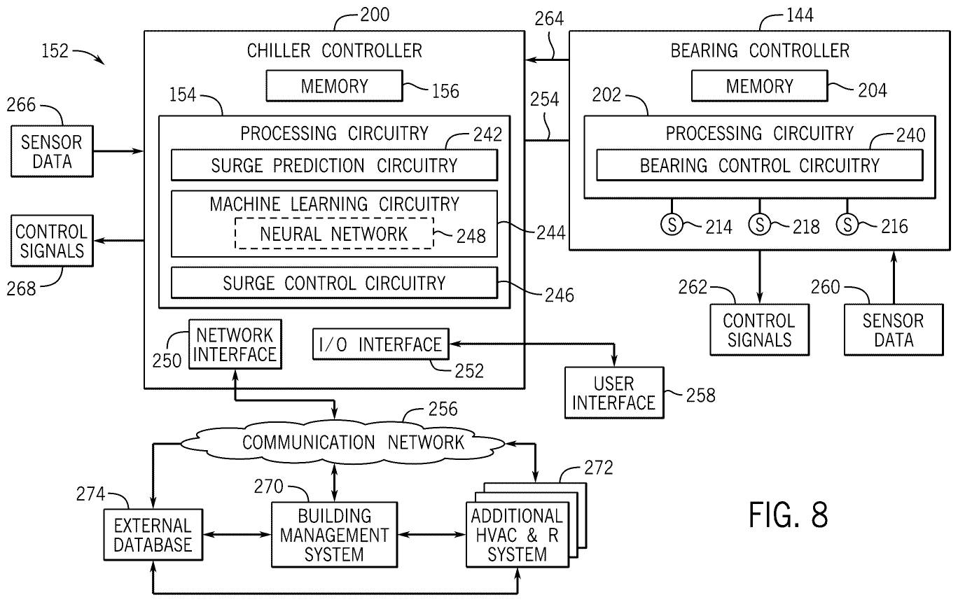

In some instances, the first position sensor 208 and the first current sensor 214 may at least partially define a first sensor system 220 associated with the first bearing 134, the second position sensor 210 and the second current sensor 216 may at least partially define a second sensor system 222 associated with the second bearing 136, and the third position sensor 212 and the third current sensor 218 may at least partially define a third sensor system 224 associated with the third bearing 138. Data collected via the respective sensors 206 of the first sensor system 220, the second sensor system 222, and the third sensor system 224 may be transmitted to and received by the bearing controller 144. The bearing controller 144 may monitor, analyze, evaluate, process, manipulate, and/or otherwise utilize the data received via the sensors 206 to predict, anticipate, detect, control, avoid, and/or rectify surge conditions and/or incipient surge of the compressor 102 in the manners described in further detail below with reference to FIG. 8.

The control system 152 may also include one or more sensors 206 configured to detect corresponding operating parameters and/or conditions associated with other operations and/or components of the compressor 102 and/or the vapor compression system 100. For example, the sensors 206 may include compressor sensors 226 configured to detect one or more operating parameters associated with operation of the compressor 102. In some embodiments, the compressor sensors 226 may include a speed sensor configured to detect a speed of the shaft 112 (e.g., rotational speed) and/or the impeller 114 (e.g., a blade tip speed of the impeller 114), one or more temperature sensors configured to detect a temperature of the working fluid directed through the compressor 102, one or more pressure sensors configured to detect a pressure of the working fluid directed through the compressor 102, a load on the compressor 102, an operating capacity or stage of the compressor 102, an operating parameter (e.g., frequency, speed) of a variable speed drive (e.g., VSD 52) configured to drive operation of the motor 118, an operating parameter of the motor 118, and so forth. For example, the compressor sensors 226 may include a suction temperature sensor, a suction pressure sensor, a discharge temperature sensor, a discharge pressure sensor, or any combination thereof.

Moreover, the one or more sensors 206 of the control system 152 may be configured to detect an operating parameter corresponding to components and/or operations of the vapor compression system 100 external to the compressor 102. For example, the one or more sensors 206 may include system sensors 228 configured to detect an operating parameter associated with the vapor compression system 100, such as a temperature of the working fluid at the evaporator 38 (e.g., evaporating temperature) and/or a temperature of the working fluid at the condenser 34 (e.g., condensing temperature), a pressure of the working fluid at the evaporator 38 (e.g., evaporating pressure) and/or a pressure of the working fluid at the condenser 34 (e.g., condensing pressure), a flow rate of the working fluid through the vapor compression system 100, a conditioning fluid temperature, pressure, and/or flow rate, a cooling fluid temperature, pressure, and/or flow rate, an ambient temperature, another suitable operating parameter, or any combination thereof. Data collected by the compressor sensors 226 and/or the system sensors 228 may be transmitted to and received by the chiller controller 200 (e.g., main controller) and may be monitored, analyzed, evaluated, processed, manipulated, recorded, and/or otherwise utilized to enable the techniques described herein. Operation of the control system 152 based on the data collected by the sensors 206 and transmitted to the bearing controller 144 and/or the chiller controller 200 is described in further detail below.

In other embodiments of the compressor 102 having bearings 132 of a different type, such as lubricant bearings and/or the porous bearings configured to receive received and discharge a pressurized fluid (e.g., working fluid, refrigerant) toward the shaft 112 and/or the collar 146, the one or more sensors 206 may be configured to detect additional or alternative operating parameters associated with operation of the bearings 132. For example, in such embodiments, the one or more sensors 206

FIG. 8 is a schematic of an embodiment of the control system 152 of the vapor compression system 100, illustrating an embodiment of the chiller controller 200 (e.g., main controller) and the bearing controller 144 that may be implemented with the vapor compression system 100 having the compressor 102 with the bearings 132 (e.g., magnetic bearings). In particular, the illustrated embodiment includes features of the chiller controller 200 and the bearing controller 144 (e.g., magnetic bearing controller) that may be incorporated in some embodiments of the vapor compression system 100. It should be appreciated that any one or more of the features illustrated in FIG. 8 may be incorporated in different embodiments of the control system 152, and in some embodiments certain features may be combined with one another, omitted, or incorporated with another component of the control system 152 and/or vapor compression system 100.

As shown, the bearing controller 144 includes bearing control circuitry 240, which may be a component of the processing circuitry 202 of the bearing controller 144 or may be incorporated with the bearing controller 144 separate from the processing circuitry 202. The chiller controller 200 includes surge prediction circuitry 242, machine learning circuitry 244, and surge control circuitry 246. In some embodiments, the machine learning circuitry 244 may include a neural network 248. The surge prediction circuitry 242, the machine learning circuitry 244, the surge control circuitry 246, or any combination thereof may be components of the processing circuitry 154 of the chiller controller 200, in some embodiments. In other embodiments, one or more of the surge prediction circuitry 242, the machine learning circuitry 244, and the surge control circuitry 246 may be integrated with the chiller controller 200 separate from the processing circuitry 154. In other embodiments, one or more of the circuitry components mentioned above may be incorporated with another controller, control board, or control system of the vapor compression system 100 (e.g., HVAC&R system). The chiller controller 200 may also include a network interface 250 and an input/output (I/O) interface 252. Details of the components mentioned above are described further below.

The chiller controller 200 and the bearing controller 144 and any combination of the components thereof may be communicatively coupled to one another via a communication bus 254 to enable transmission of data, signals, and/or other information to and from one another to enable implementation of the techniques described herein. The communication bus 254 may include one or more bus lines, such as a data bus line, an address bus line, and a control bus line. Data and signal transmission between the bearing controller 144 and the chiller controller 200 during operation of the control system 152 to predict incipient surge and avoid onset of surge conditions is described further below.

The network interface 250 is configured to enable transmission of data, signals, and/or other information between the chiller controller 200 and other components or system external to the control system 152. In some embodiments, the network interface 250 may also enable communication between the chiller controller 200 and components of the control system 152, such as one or more of the sensors 206. Additionally or alternatively, one or more components of the compressor 102 (e.g., the motor 118, the VSD 52) and/or vapor compression system 100 may be directly communicatively coupled to the chiller controller 200. For example, the network interface 250 may include wired interfaces and/or wireless interfaces (e.g., jacks, antennas, transmitters, receivers, transceivers, wire terminals, etc.) configured to facilitate data communications between the chiller controller 200 and various systems, devices, or networks of the vapor compression system 100, such as via a communication network 256. In some embodiments, the network interface 250 may include an Ethernet card and a port configured to send and receive data via an Ethernet-based communications network and/or a Wi-Fi transceiver configured to enable communications (e.g., data transmission) via a wireless communications network (e.g., communication network 256). The network interface 250 may be configured to enable data communication to and from the chiller controller 200 via a local area network and/or a wide area networks (e.g., the Internet, a building WAN) and may implement one or more communication protocols (e.g., BACnet, IP, LON, IDNAC, Modbus, etc.).

The I/O interface 252 is configured to enable a communicative connection between the chiller controller 200 and one or more I/O devices, such as a user interface 258. The user interface 258 may include a display, a keyboard, a touchscreen, a cursor control device, a scroll wheel, one or more buttons, another suitable user I/O device, or any combination thereof. In any case, the user interface 258 and the I/O interface 252 are configured to enable a user to interface (e.g., interact) with the chiller controller 200. In some embodiments, the user interface 258 and the I/O interface 252 are configured to enable a user to interface with the bearing controller 144. The user interface 258 may be configured to receive a user input, such as to adjust an operating parameter of the control system 152 and/or to modify data stored on the memory 156 of the chiller controller 200 and/or the memory 204 of the bearing controller 144. The user interface 258 may also enable the chiller controller 200 and/or the bearing controller 144 to output data (e.g., sensor data) and/or communications (e.g., an alert) to a user. In some embodiments, the bearing controller 144 may include a separate embodiment of the I/O interface 252 integrated therewith to enable a communicatively connection between the bearing controller 144 and another user interface 258.

As described above, the bearing controller 144 is communicatively coupled to one or more sensors 206 of the control system 152 and is configured to receive sensor data 260 (e.g., signals, feedback) detected by one or more of the sensors 206, such as the position sensors 208, 210, and 212 (e.g., radial position sensors, axial position sensors). Certain sensors 206, such as the current sensors 214, 216, and 218 may be integrated with the bearing controller 144. Based on the sensor data 260 and/or feedback received from the position sensors 208, 210, and 212 and the current sensors 214, 216, and 218, the bearing control circuitry 240 may operate to evaluate operation of the bearings 132 and, in some instances, determine an appropriate control action to implement in order to adjust operation of one or more of the bearings 132.

For example, the bearing control circuitry 240 may execute instructions or code (e.g., stored on the memory 204) to determine a position of the shaft 112 within the housing 110, such as a radial position of the shaft 112 (e.g., relative to the longitudinal axis 104), an axial position of the shaft 112 (e.g., along the rotational axis 126), or both. In response to a determination that the position of the shaft 112 is not a desired position (e.g., the rotational axis 126 of the shaft 112 is not axially aligned or coaxial with the longitudinal axis 104), the bearing control circuitry 240 may determine and implement a remedial or corrective action and output one or more control signals 262 to enable an adjustment to the position of the shaft 112. For example, the bearing control circuitry 240 may operate to adjust an amount or magnitude of electrical current supplied to one or more of the bearings 132. In this way, a magnetic force applied to the shaft 112 and/or the collar 146 may be adjusted to effectuate a positional adjustment of the shaft 112 (e.g., along the longitudinal axis 104 and/or in the radial direction 106) and adjust the shaft 112 toward a desired position.

The sensor data 260 transmitted to the bearing controller 144 (e.g., the processing circuitry 202) from one or more of the sensors 206 may also be utilized to implement the present techniques and predict incipient surge conditions (e.g., pre-surge conditions). For example, data and/or feedback received from one or more of the position sensors 208, 210, and 212 (e.g., eddy current sensors) may be processed by the processing circuitry 202 to determine a vibration frequency (e.g., radial vibration frequency, vibration value, vibration parameter) of the shaft 112 and/or a magnitude of vibration (e.g., vibration value, vibration parameter, vibration amplitude) of the shaft 112. To this end, the processing circuitry 202 may be configured to execute one or more algorithms or other instructions stored on the memory 204 to process the sensor data 260 received from the position sensors 208, 210, and/or 212 and determine the vibration frequency and/or the magnitude of vibrations of the shaft 112. In some embodiments, the sensor data 260 received from the second position sensor 210 and the third position sensor 212 (e.g., radial position sensors) may be processed to determine a vibration frequency (e.g., radial vibration frequency) and radial vibration magnitude (e.g., increased amount of change in radial position) of the shaft 112, and the sensor data 260 received from the first position sensor 208 (e.g., axial position sensor) may be processed to determine a severity of an incipient surge condition.

As will be appreciated, the position sensors 208, 210, and 212 associated with the bearings 134, 136, and 138 (e.g., magnetic bearings) may be configured to collect data indicative of an axial and/or radial position of the shaft 112 at high sampling rates. Thus, changes in the vibration frequency and/or a magnitude (e.g., amplitude) of vibrations of the shaft 112 may be rapidly and more accurately determined and/or detected by the bearing controller 144. In some embodiments, the control system 152 may determine that an incipient surge condition exists and/or that compressor surge condition is approaching in response to a determination that a vibration amplitude of the shaft 112 (e.g., peak radial position of the shaft 112 offset from the longitudinal axis 104) increases at a frequency (e.g., vibration frequency) that is less than a running speed frequency of the shaft 112. As will be appreciated, the running speed frequency of the shaft 112 may be expressed as a value of the speed of the shaft 112 (e.g., detected by one of the compressor sensors 226) divided by 60. In other words, greater changes in the radial position of the shaft 112 (e.g., above a threshold radial position or radial position offset value) at a frequency that is less than a corresponding speed frequency of the shaft 112 may be detected by the bearing controller 144, and the bearing controller 144 may consequently determine that incipient compressor surge is present.

Additionally, data and/or feedback received from one or more of the current sensors 214, 216, and 218 may be processed by the processing circuitry 202 to determine a respective force (e.g., magnetic force) applied to the shaft 112 and/or the collar 146 via the bearings 134, 136, and 138. In particular, a magnitude of electrical current applied to the first bearing 134 (e.g., thrust bearing) may be processed or evaluated by the processing circuitry 202 (e.g., via execution of an algorithm or instructions stored on the memory 204) to determine a magnetic force applied to the collar 146 along the longitudinal axis 104, such as in the first direction 148 or in the second direction 150. Respective magnitudes of electrical current applied to the second bearing 136 and the third bearing 138 (e.g., radial bearings) may be processed or evaluated by the processing circuitry 202 to determine a respective magnetic force applied to the shaft 112 in the radial direction 106.

In order to more reliably detect incipient surge conditions and/or predict onset of actual surge conditions, the processing circuitry 202 is configured to process and/or evaluate the data received from the current sensors 214, 216, and 218 to determine average forces and/or steady state forces (e.g., radial forces, axial forces) applied to the shaft 112 and/or the collar 146 via the bearings 132. That is, the processing circuitry 202 may execute one or more algorithms or sets of executable instructions (e.g., stored on the memory 204) to determine a respective average or steady state radial force applied to the shaft 112 via the second bearing 136 and the third bearing 138, and the processing circuitry 202 may execute one or more algorithms or sets of executable instructions (e.g., stored on the memory 204) to determine an average or steady state axial force applied to the collar 146 via the first bearing 134.

As should be appreciated by those skilled in the art, a rapid or sudden shift (e.g., change, alteration) in one or more of the magnetic forces applied to the shaft 112 and/or collar 146 may be indicative of an incipient surge condition. In accordance with present techniques, the processing circuitry 202 may be configured to detect changes or shifts in the radial magnetic forces and/or axial magnetic force imparted to the shaft 112 via the bearings 132, as well as detect a rate of change (e.g., slope) in the radial magnetic forces and/or in the axial magnetic force. In some embodiments, the processing circuitry 202 may be configured to determine a respective rate of change of the axial magnetic force (e.g., imparted by the first bearing 134) and/or of one or more of the radial magnetic forces (e.g., imparted by the second bearing 136 and/or the third bearing 138) and compare the one or more rates of change in the magnetic forces to a corresponding threshold rate of change (e.g., threshold value, reference value, rate of change threshold, stored in the memory 204) associated with the particular magnetic force (e.g., radial magnetic force, axial magnetic force). Additionally or alternatively, the processing circuitry 202 may be configured to determine, detect, or identify a directional change, angular change, and/or reversal (e.g., directional reversal, change in radial direction, angular radial change) in a magnetic force applied by one or more of the bearings 132 to the shaft 112. As discussed above, the processing circuitry 202 may also compare a determined vibration frequency and/or vibration amplitude of the shaft 112 (e.g., based on sensor data 260 from one or more of the position sensors 208, 210, and 212 to a corresponding threshold value (e.g., frequency value, frequency threshold, amplitude value, amplitude threshold) stored in the memory 204.

Based on a detected reversal in one or more of the magnetic forces, based on a determination that a rate of change of one or more of the magnetic forces imparted by one of the bearings 132 exceeds a corresponding threshold rate of change value, based on a determination that a magnitude of vibrations of the shaft 112 (e.g., a magnitude of a change in radial position, radial vibration amplitude) exceeds a corresponding threshold value at a particular vibration frequency and/or within a range of vibration frequencies (e.g., less than a running speed frequency of the shaft 112), or any combination thereof, the bearing controller 144 may determine that an incipient surge condition is present. In some embodiments, the processing circuitry 202 may be configured to determine that an incipient surge condition is present based on a sequence (e.g., order in time) in which two or more of the determinations described above is made. For example, in response to a first determination that vibrations of the shaft 112 exists below a threshold vibration frequency (e.g., equal to or corresponding to a speed frequency of the shaft 112) and a second determination, subsequent to the first determination (e.g., within a threshold amount of time), that a steady state magnetic force applied via one of the bearings (e.g., radial magnetic bearing, axial magnetic bearing, or both) changes above a threshold rate of change and/or changes and/or reverses in direction, the bearing controller 144 may determine that an incipient surge condition is present.

In response to an identified, detected, or determined incipient surge condition, the bearing controller 144 may output one of the control signals 262 and/or other signal to one or more of the bearings 132 and/or to the chiller controller 200 to implement an operational adjustment to the vapor compression system 100 (e.g., the compressor 102) and/or to the bearings 132. For example, the chiller controller 200 may receive one of the control signals 262 indicative of an incipient surge condition, the chiller controller 200 may implement a remedial control action to avoid onset of the surge condition (e.g., an actual surge condition). In some instances, the remedial control action implemented by the chiller controller 200 may cause an adjustment to operation of the motor 118 (e.g., VSD 52), such as to increase a speed of the shaft 112 and the impeller 114. Additionally or alternatively, upon receipt of the control signal 262 indicative of an incipient surge condition from the bearing controller 144, the chiller controller 200 may evaluate and/or process the control signal 262 in combination with additional information, such as data from other sensors 206 of the control system 152, data stored on the memory 156, and/or other information to determine whether a remedial control action to avoid onset of a surge condition should be implemented. In other words, the chiller controller 200 may predict whether the surge condition is imminent based on the control signal 262 and additional data received by the chiller controller 200 and/or stored in the memory 156. In some embodiments, the bearing controller 144 may be configured to transmit (e.g., via the communication bus 254) one or more of the determined values and/or corresponding threshold values (e.g., rate of change value, vibration frequency value, vibration amplitude value, steady state force value, corresponding threshold values) to the chiller controller 200 instead of or in addition to the control signal 262 to enable identification of an incipient surge condition and/or to predict onset of an actual surge condition.

To further improve reliability in detection of incipient surge conditions and/or prediction of onset of actual surge conditions, the bearing controller 144 may be configured to process and/or manipulate different types of the sensor data 260 in combination with one another. In some embodiments, the processing circuitry 202 may be configured to execute one or more algorithms (e.g., a surge predictive algorithm) stored on the memory 204 that utilize values associated one or more magnetic forces, vibration frequency, vibration magnitude (e.g., amplitude), or any combination thereof, as inputs. For example, the processing circuitry 202 may determine a respective rate of change value of a steady state radial magnetic force (e.g., determined via data from one or more of the current sensors 216 and 218), determine a vibration frequency value and/or vibration magnitude of the shaft 112 (e.g., determined via data from one or more of the position sensors 210 and 212), and apply the rate of change value, the vibration frequency value, the vibration magnitude (e.g., amplitude) value, or any combination thereof as inputs to the surge predictive algorithm. Upon execution of the surge predictive algorithm, the processing circuitry 202 may generate an output, such as a digital signal 264 having a dimensionless value. The digital signal 264 may be transmitted from the bearing controller 144 to the chiller controller 200 (e.g., via the communication bus 254) for further evaluation and processing to predict an incipient surge condition.

While the present discussion describes the bearing controller 144 as being configured to determine values associated with magnetic forces, vibration frequencies, vibration amplitudes, and corresponding metrics (e.g., rate of change, average) of the shaft 112, it should be appreciated that the chiller controller 200 and/or a combination of the bearing controller 144 and the chiller controller 200 may perform such operations and/or calculations in other embodiments of the control system 152. For example, the chiller controller 200 may be configured to receive some or all of the sensor data 260 described above (e.g., directly from the sensors 206), perform one or more of the calculations and/or determinations described above, perform one or more additional calculations and/or determinations based on the sensor data 260, or any combination thereof.

Upon receipt of one or more of the control signals 262 and/or the digital signal 264 (e.g., dimensionless value) from the bearing controller 144, the chiller controller 200 may operate to further evaluate the one or more control signals 262 and/or the digital signal 264 (e.g., a value of the digital signal 264) to determine and/or confirm whether incipient surge is detected and/or to predict onset of an actual surge condition. For example, the chiller controller 200 may be configured to evaluate the one or more control signals 262 and/or the digital signal 264 in combination with sensor data 266 and/or sensor data 260 received from one or more of the sensors 206 of the control system 152 (e.g., compressor sensors 226, system sensors 228, etc.). In some embodiments, the chiller controller 200 may be configured to receive sensor data 266 from one or more of the compressor sensors 226 indicative of a temperature and/or pressure of a working fluid at the suction inlet 120 of the compressor 102, a temperature and/or pressure of a working fluid at a discharge of the compressor 102, or both.

As mentioned above, the chiller controller 200 (e.g., the processing circuitry 154) includes the surge prediction circuitry 242, the machine learning circuitry 244, and the surge control circuitry 246. It should be appreciated that the functions and operations of the circuitries may be performed via execution of corresponding algorithms, sets of executable instructions, and/or other code stored on the memory 156 of the chiller controller 200 and/or other memory.

The surge prediction circuitry 242 may be configured to evaluate one or more inputs to determine the presence of an incipient surge condition and/or to predict the onset of an actual surge condition. For example, the surge prediction circuitry 242 may receive the digital signal 264 and compare the digital signal 264 (e.g., dimensionless value) to a corresponding threshold value, which may be stored in the memory 156. In some embodiments, a plurality of threshold values corresponding to the digital signal 264 may be stored on the memory 156. The surge prediction circuitry 242 may select a particular threshold value (e.g., digital signal threshold value) based on one or more factors (e.g., data, conditions, parameters). For example, the memory 156 may include a database (e.g., look up table) correlating different threshold values with corresponding temperature and/or pressure values of the working fluid, the evaporator 38, and/or the condenser 34). The surge prediction circuitry 242 may receive sensor data 266 (e.g., from the system sensors 228 and/or the compressor sensors 226) indicative of one or more existing or current temperatures and/or pressures (e.g., within the vapor compression system 100, suction and/or discharge values, evaporator and/or condenser values) and may reference the database in the memory 156 to select the particular threshold value corresponding to temperature and/or pressure values that are most closely representative of the current temperatures and/or pressures detected by the sensors 206. The threshold values stored in the memory 156 may be established based on testing, experimental procedures, prior or historical operation of the vapor compression system 100, or any combination thereof. Additionally or alternatively, as discussed further below, one or more of the threshold values may be iteratively adjusted by the chiller controller 200 based on further operation of the vapor compression system 100 and/or based on determinations made by the machine learning circuitry 244.

Upon comparison of the value of the digital signal 264 with a corresponding threshold value, the surge prediction circuitry 242 may determine whether the value of the digital signal 264 exceeds the threshold value. In response to a determination that the value of the digital signal 264 exceeds the threshold value, the surge prediction circuitry 242 may determine that an incipient surge condition is present and/or that onset of an actual surge condition is imminent. Based on such a determination, the surge control circuitry 246 may output a control signal 268 to implement a remedial action or adjustment to the vapor compression system 100 to avoid onset of the actual surge condition. For example, the surge control circuitry 246 may instruct the motor 118 (e.g., VSD 52) to increase a speed of the motor 118 and therefore the impeller 114 to avoid onset of the surge condition. The surge control circuitry 246 may implement any additional or alternative control action to implement an adjustment to the compressor 102 and/or another component of the vapor compression system 100 to avoid onset of an actual surge condition, such as adjusting a position of a value (e.g., hot gas bypass, valve expansion valve), adjusting a speed of a pump or other motor, adjusting a speed of a fan, adjusting a position of a variable geometry diffuser of the compressor 102, and so forth.

In response to a determination that the value of the digital signal 264 does not exceed the corresponding threshold, the surge prediction circuitry 242 may continue monitoring the sensor data 266, the sensor data 260, and/or data or signals received from the bearing controller 144 to detect future incipient surge conditions and/or predict onset of future actual surge conditions.

Similar to the above, the surge prediction circuitry 242 may be configured to compare any one or combination of the determined or received parameter values discussed above (e.g., magnetic force value, steady state force value, vibration frequency, vibration amplitude, shaft 112 position, electrical current value, etc.) to a corresponding threshold value stored in the memory 156 to enable a determination of whether an incipient surge condition exists and/or to predict onset of a surge condition. In some embodiments, the surge prediction circuitry 242 may receive one or more of the data values and/or parameters described above and monitor the one or more values to determine whether an observed pattern (e.g., successive or sequential values) of the one or more values match or substantially match (e.g., correlate within a threshold degree) a corresponding pattern of one or more values stored in the memory 156 that is recorded as indicative of an incipient surge condition and/or onset of an actual surge condition (e.g., previously experienced by the vapor compression system 100 or another vapor compression system).

Additionally or alternatively, subsequent to identification of the incipient surge condition, the surge prediction circuitry 242 may also record (e.g., in the memory 156) an indication of whether or not an actual surge condition occurred and/or data from the sensors 206 corresponding thereto following the identified incipient surge condition. In this way, the surge prediction circuitry 242 may more accurately and reliably predict incipient surge and avoid onset of actual surge in the compressor 102 in future operations of the compressor 102. As similarly described above, the surge prediction circuitry 242 may determine that the compressor 102 undergoes surge based on comparison of one or more received values from the sensors 206 (e.g., sensor data 260, 266) described herein with corresponding surge threshold values. For example, an actual surge condition may be based on data from sensors 206 such as a working fluid pressure sensor, a working fluid temperature sensor, a working fluid flow rate sensor, the position sensors 208, 210, and 212, the current sensors 214, 216, and 218, an impeller 114 speed sensor, another suitable sensor, or any combination thereof. In response to a determination that the compressor 102 undergoes an actual surge condition, the surge prediction circuitry 242 may record data (e.g., surge data, pre-surge data, sensor data 260, 266, working fluid pressure/temperature data, suction data, discharge data, flow rate data, shaft 112 vibration data, bearing 132 position data, shaft 112 speed data, impeller 114 speed data) in the memory 156 that is detected and/or received during the actual surge condition, as well as detected and/or received in the immediately preceding time period (e.g., 1 second, 2 seconds, 3 seconds, 5 seconds, 10 seconds) before the onset of the surge condition. In this way, the chiller controller 200 may reference the stored surge data and pre-surge data during subsequent operation of the compressor 102 to enable improved identification of incipient surge conditions and prediction of onset of actual surge conditions. It should be noted that data similar to that described above may be recorded in the memory 156 after identification of an incipient surge condition and upon successful avoidance of an onset of an actual surge condition.

In order to further improve identification of incipient surge conditions in ongoing, subsequent, or future operations of the vapor compression system 100, the chiller controller 200 also includes the machine learning circuitry 244 (e.g., automated adjustment circuitry). The machine learning circuitry 244 may be configured to iteratively adjust and/or re-adjust the one or more threshold values and/or other data stored in the memory 156 and/or the memory 204 based on observed operations of the vapor compression system 100, based on accurate identifications of incipient surge conditions, based on subsequent, successful avoidance of actual surge conditions, and/or based on onset of actual surge conditions after identification of incipient surge conditions. In other words, the machine learning circuitry 244 may dynamically adjust the threshold values and/or other data stored in the memory 156 and/or memory 204 based on observed or detected conditions or parameters of the compressor 102 that may vary and/or change in different operations of the vapor compression system 100 at different times. In this way, an operating map of the compressor 102 may be interactively adjusted and improved to enable more efficient operation of the compressor 102 (e.g., closer to the surge line) and more reliable avoidance of the onset of surge conditions.

In some embodiments, the machine learning circuitry 244 may include the neural network 248 configured to enable improved functionality of the machine learning circuitry 244, such as improved monitoring of incipient surge conditions and/or onset of actual surge conditions that result from different operations of the compressor 102 with different operating parameter values (e.g., temperature, pressure, speed, etc.) and/or improved (e.g., more acute) adjustment of threshold values stored in the memory 156 and/or the memory 204. In this way, the neural network 248 may enable more accurate and reliable identification of incipient surge conditions, as well as more accurate and reliable prediction and avoidance of onset of actual surge conditions. Moreover, operation of the compressor 102 may be improved, as the chiller controller 200 may operate the compressor 102 closer to the surge line while also reliably avoiding onset of actual surge conditions. For example, the compressor 102 may be operated with reduced energy consumption and greater efficiency, a useful life of the compressor 102 may be extended, and/or unscheduled maintenance may be avoided by avoiding onset of actual surge condition.

The neural network 248 may be or include an Artificial Neural Network (ANN) model, a Convolutional Neural Network (CNN) model, a Recurrent Neural Network (RNN) model, or any combination thereof. In some embodiments, the neural network 248 may be initially configured with and/or trained to build a map (e.g., a continuous map) of operating conditions over an entire operating range of test machine (e.g., test compressor representative of the compressor 102). The neural network 248 may be configured or trained based on operating parameters of the test machine under normal conditions, incipient or pre-surge conditions, and surge conditions. For example, training data used for training the neural network 248 may be obtained by operating one or more test machines under normal conditions, pre-surge conditions, and surge conditions. When the training data (e.g., compressor operating parameter data, radial and/or axial shaft position data, bearing magnetic force data, data of electrical current supplied to radial and/or axial bearings, and so forth under normal conditions, pre-surge conditions, and surge conditions) is provided to the neural network 248, the neural network 618 may determine, learn, and/or establish weights, which may be subsequently adjusted via the machine learning circuitry 244 based on compressor 102 operation, for different parameters and may generate a continuous map of conditions over an entire operating range of the test machine. The weights of the different parameters may be indicative of a significance or relevance (e.g., impact value) of the parameter as concerns identification of incipient surge and/or onset of actual surge. The continuous map of compressor operating conditions may include data during normal operating conditions, pre-surge conditions, and surge conditions. Examples of the compressor operating parameters may include, but are not limited to, an operating mode of the compressor, position of a variable geometry diffuser of the compressor, suction and discharge pressures, operating head value of the compressor, compressor motor rotation speed, and so forth. The data (e.g., sensor data 260 and 266) received and/or determined by the bearing controller 144 and/or the chiller controller 200 may also be utilized as inputs of the neural network 248 and/or the machine learning circuitry 244 to enable improved adjustment of threshold values and an operating map of the compressor 102.

As mentioned above, the control system 152 may be communicatively coupled to the communication network 256 to enable transmission of data, control signals, and/or other information with systems external to the vapor compression system 100. For example, the control system 152 may be communicatively coupled to a building management system 270 that services a building having the vapor compression system 100, one or more additional HVAC&R systems 272 (e.g., installed at the same location or with the same building as the vapor compression system 100), and/or an external database 274, such as a database of a manufacturer of the vapor compression system 100. The data and/or other information received, determined, and/or stored by the control system 152 may be transmitted to the building management system 270, one or more additional HVAC&R systems 272, and/or the external database 274 for further reference, evaluation, and/or other use. For example, the data and/or other information transmitted by the control system 152 may be utilized by the building management system 270 and/or the one or more additional HVAC&R systems 272 to enable improved operation of the additional HVAC&R systems 272. The data and/or other information transmitted by the control system 152 may also be referenced in the external database 274 to enable improved manufacturing, configuration, programming, maintenance, and/or other operations (e.g., prediction and avoidance of surge) for other embodiments of the vapor compression system 100 and/or other HVAC&R systems.

As discussed above, present embodiments are directed to systems and methods for predicting and avoiding compressor surge conditions in a more reliable manner. In this way, HVAC&R systems incorporating the present techniques may operate compressors at operating points on a performance map of the compressor that are closer to the surge line while also avoiding onset of surge conditions. Specifically, present embodiments include the utilization of sensor data and/or feedback associated with one or more bearings (e.g., magnetic bearings) of the compressor to evaluate compressor operation, predict incipient surge conditions, and implement requisite remedial actions to avoid the onset of surge conditions (e.g., actual surge conditions). For example, the sensor data and/or feedback may be indicative of a position (e.g., radial position, axial position) of a shaft of the compressor, a force (e.g., radial force, axial force) exerted on the shaft of the compressor, or both. The sensor data and/or feedback may be evaluated, processed, and/or compared to one or more threshold values (e.g., threshold values) to determine whether an incipient surge condition exists and/or to predict whether actual surge condition is approaching and/or expected. Additionally, the present systems and methods may incorporate machine learning techniques to enable iterative adjustment of the one or more threshold values based on collected and recorded operating data of the HVAC&R system. In this way, prediction and avoidance of surge conditions may be continually improved with subsequent operation of the HVAC&R system, which may enable more efficient operation of the HVAC&R system over time.

While only certain features and embodiments have been illustrated and described, many modifications and changes may occur to those skilled in the art (e.g., variations in sizes, dimensions, structures, shapes and proportions of the various elements, values of parameters (e.g., temperatures, pressures, etc.), mounting arrangements, use of materials, colors, orientations, etc.) without materially departing from the novel teachings and advantages of the subject matter recited in the claims. The order or sequence of any process or method steps may be varied or re-sequenced according to alternative embodiments. It is, therefore, to be understood that the appended claims are intended to cover all such modifications and changes as fall within the true spirit of the invention.

Furthermore, in an effort to provide a concise description of the exemplary embodiments, all features of an actual implementation may not have been described, such as those unrelated to the presently contemplated best mode, or those unrelated to enablement. It should be appreciated that in the development of any such actual implementation, as in any engineering or design project, numerous implementation specific decisions may be made. Such a development effort might be complex and time consuming, but would nevertheless be a routine undertaking of design, fabrication, and manufacture for those of ordinary skill having the benefit of this disclosure, without undue experimentation.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112(f). However, for any claims containing elements designated in any other manner, it is intended that such elements are not to be interpreted under 35 U.S.C. 112(f).

1. A heating, ventilation, air conditioning, and refrigeration (HVAC&R) system, comprising:
a compressor comprising a shaft and a bearing system configured to support the shaft during rotation;
a plurality of sensors configured to detect a plurality of operating parameter values of the compressor, the bearing system, or both; and
a control system communicatively coupled to the plurality of sensors, wherein the control system is configured to:
receive data indicative of the plurality of operating parameter values from the plurality of sensors;
determine a rate of change of a steady state force applied to the shaft by the bearing system based on data received from a first sensor of the plurality of sensors;
determine a vibration value of the shaft based on data received from a second sensor of the plurality of sensors; and
predict an incipient surge condition of the compressor based on the rate of change and the vibration value.

2. The HVAC&R system of claim 1, wherein the bearing system comprises a magnetic bearing, and the magnetic bearing is configured to apply the steady state force to the shaft.

3. The HVAC&R system of claim 2, wherein the first sensor is a current sensor configured to detect a magnitude of an electrical current supplied to the magnetic bearing, the data received from the first sensor comprises the magnitude of the electrical current, and the control system is configured to determine the steady state force applied to the shaft based on the magnitude of the electrical current.

4. The HVAC&R system of claim 3, wherein the magnetic bearing is a radial bearing configured to support the shaft in a radial direction, cross-wise to a rotational axis of the shaft.

5. The HVAC&R system of claim 3, wherein the control system comprises a magnetic bearing controller configured to regulate operation of the bearing system, and the current sensor is integrated with the magnetic bearing controller.

6. The HVAC&R system of claim 2, wherein the second sensor is a position sensor configured to detect a position of the shaft relative to the magnetic bearing.

7. The HVAC&R system of claim 6, wherein the data received from the second sensor comprises a plurality of values indicative of the position of the shaft, the control system is configured to determine the vibration value based on the plurality of values, and the vibration value comprises a magnitude of vibration or a frequency of vibration.

8. The HVAC&R system of claim 1, wherein the control system comprises:
a bearing controller configured to regulate operation of the bearing system; and
a main controller configured to regulate operation of the compressor,
wherein the bearing controller is configured to execute an algorithm to generate a digital signal based on the rate of change of the steady state force and based on the vibration value, the bearing controller is configured to transmit the digital signal to the main controller, and the main controller is configured to predict the incipient surge condition based on the digital signal.

9. The HVAC&R system of claim 8, wherein the main controller is configured to compare a value of the digital signal to a threshold value stored in a memory of the main controller, and the main controller is configured to predict the incipient surge condition based on a determination that the value of the digital signal exceeds the threshold value.

10. The HVAC&R system of claim 9, wherein the value of the digital signal is dimensionless.

11. The HVAC&R system of claim 9, wherein the threshold value is one of a plurality of threshold values stored in the memory of the main controller, and the main controller is configured to select the threshold value from the plurality of threshold values based on sensor data received from a third sensor of the plurality of sensors.

12. A control system for a heating, ventilation, air conditioning, and refrigeration (HVAC&R) system, wherein the control system is configured to:
receive first data from a first sensor of the control system, wherein the first data is indicative of a position of a shaft of a centrifugal compressor;
receive second data from a second sensor of the control system, wherein the second data is indicative of an amount of electrical current supplied to a magnetic bearing configured to support the shaft of the centrifugal compressor;
determine a vibration parameter of the shaft based on the first data;
determine a steady state force applied to the shaft by the magnetic bearing based on the second data;
identify an incipient surge condition of the centrifugal compressor based on the vibration parameter and the steady state force; and
adjust operation of the centrifugal compressor based on identification of the incipient surge condition.

13. The control system of claim 12, wherein the control system is configured to:
determine a rate of change of the steady state force based on the second data; and
identify the incipient surge condition of the centrifugal compressor based on the vibration parameter and the rate of change of the steady state force.

14. The control system of claim 13, comprising:
a magnetic bearing controller configured to regulate operation of the magnetic bearing, receive the first data and the second data, determine the vibration parameter, determine the rate of change of the steady state force, and generate a digital signal based on the vibration parameter and the rate of change of the steady state force; and
a main controller communicatively coupled to the magnetic bearing controller, wherein the main controller is configured to regulate operation of the centrifugal compressor, receive the digital signal from the magnetic bearing controller, and identify the incipient surge condition based on the digital signal.

15. The control system of claim 14, wherein the main controller is configured to increase a speed of the centrifugal compressor to adjust operation of the centrifugal compressor.

16. The control system of claim 14, wherein the first sensor comprises an eddy current sensor coupled to the magnetic bearing, and the eddy current sensor is configured to detect the position of the shaft relative to the magnetic bearing, and wherein the second sensor is a current sensor integrated with the magnetic bearing controller.

17. The control system of claim 14, wherein the main controller is configured to:
select a threshold value of a plurality of threshold values stored on a memory of the main controller based on a speed of the shaft, pressure data received by the main controller, temperature data received by the main controller, or any combination thereof;
compare a value of the digital signal to the threshold value; and
identify the incipient surge condition based on comparison of the value of the digital signal to the threshold value.

18. A chiller of heating, ventilation, air conditioning, and refrigeration (HVAC&R) system, comprising:
a compressor comprising a motor and a shaft configured to drive rotation of an impeller;
a magnetic bearing configured to support the shaft;
a current sensor configured to detect a magnitude of an electrical current supplied to the magnetic bearing;
a position sensor coupled to the magnetic bearing and configured to detect a position of the shaft relative to the magnetic bearing;
a magnetic bearing controller configured to supply the electrical current to the magnetic bearing, wherein the magnetic bearing controller is configured to receive first data indicative of the magnitude of electrical current and receive second data indicative of the position of the shaft relative to the magnetic bearing; and the magnetic bearing controller is configured to generate a signal based on the first data and the second data; and
a chiller controller communicatively coupled to the magnetic bearing controller, wherein the chiller controller is configured to regulate operation of the compressor, receive the signal from the magnetic bearing controller, compare a value of the signal to a threshold value, and identify an incipient surge condition of the compressor based on comparison of the value of the signal to the threshold value.

19. The chiller of claim 18, wherein the chiller controller comprises circuitry configured to adjust the threshold value based on the first data, based on the second data, based on additional data received from an additional sensor, based on identification of the incipient surge condition, based on detected onset of an actual surge condition of the compressor, or any combination thereof.

20. The chiller of claim 18, wherein the magnetic bearing controller is configured to execute an algorithm utilizing the first data and the second data as inputs to generate the signal, wherein the value of the signal is dimensionless.
